(19) United States
(12) Patent Application Publication
(10) Pub. No.: US 2026/0313789 A1
(43) Pub. Date: Oct. 8, 2026

(54) FLEXIBLE CIRCUIT BOARD AND MANUFACTURING METHOD THEREFOR

(71) Applicant: POMIRAN METALIZATION RESEARCH CO., LTD., TAOYUAN CITY (TW)

(72) Inventors: WEN-CHIN CHEN, TAOYUAN CITY (TW); CHI-HUAN LO, TAOYUAN CITY (TW); CHUNG-YI CHEN, TAOYUAN CITY (TW)

(73) Assignee: POMIRAN METALIZATION RESEARCH CO., LTD., TAOYUAN CITY (TW)

(21) Appl. No.: 19/280,138

(22) Filed: Jul. 25, 2025

(30) Foreign Application Priority Data
Apr. 7, 2025 (TW) 114112991

(51) Int. Cl. H05K 1/02; H05K 1/03; H05K 1/11; H05K 3/00; H05K 3/10

(52) U.S. Cl. CPC H05K 1/0277; H05K 1/0213; H05K 1/0313; H05K 1/115; H05K 3/0011; H05K 3/10; H05K 2201/0154

(57) ABSTRACT

A high-aspect-ratio flexible circuit board and a manufacturing method are provided. The high-aspect-ratio flexible circuit board includes a plastic substrate, a metal seed layer, and a copper trace layer. The plastic substrate includes a first surface and a second surface opposite to each other, where a first patterned groove is formed in the first surface and/or a second patterned groove is formed in the second surface, and an upper limit of a sum value of a total depth of the first patterned groove and a total depth of the second patterned groove equals a thickness of the plastic substrate minus 5 μm. The metal seed layer is formed on the first surface and/or the second surface. The copper trace layer is formed on the metal seed layer corresponding to each of the first patterned groove and/or the second patterned groove.

### CROSS-REFERENCE TO RELATED APPLICATION

This non-provisional application claims priority under 35 U.S.C. § 119 (a) on Patent Application No(s). 114112991 filed in Taiwan, R.O.C. on Apr. 7, 2025, the entire contents of which are hereby incorporated by reference.

### BACKGROUND OF THE INVENTION

### 1. Field of the Invention

The present disclosure relates to a flexible circuit board, and in particular to a flexible circuit board with a high aspect ratio.

### 2. Description of the Related Art

Flexible circuit boards are a circuit board mainly made of polyimide and copper clad, and they have advantages of flexibility, heat resistance and lightweight and thin profiles. Among the flexible circuit boards, a flexible circuit board applied to a voice coil motor has characteristics of high aspect ratio and fine pitch, and the flexible circuit board is made by photolithography in combination with pattern plating in a conventional manufacturing process.

### BRIEF SUMMARY OF THE INVENTION

However, conventional high-aspect-ratio flexible circuit boards still have the following problems to be solved. In a circuit patterning process of high-aspect-ratio flexible circuit boards, especially for a design with a trace pitch not more than 60 μm, a limited standing area of a dry-film photoresist on a circuit board may easily cause a dry film to peel off from the circuit board in the manufacturing processes of exposure and development, so that defects are generated in a trace pattern formed in the subsequent copper plating process, thereby resulting in trace short. Therefore, how to avoid that the dry-film photoresist on the high-aspect-ratio flexible circuit board peels off due to the limited standing area is still a problem to be solved.

An object of the present disclosure is to provide a high-aspect-ratio flexible circuit board for the above problems, the high-aspect-ratio flexible circuit board including: a plastic substrate, including a first surface and a second surface opposite to each other, where a first patterned groove is formed in the first surface and/or a second patterned groove is formed in the second surface, and an upper limit of a sum value of a total depth of the first patterned groove and a total depth of the second patterned groove equals a thickness of the plastic substrate minus 5 μm; a metal seed layer, formed on the first surface and/or the second surface; and a copper trace layer, formed on the metal seed layer corresponding to each of the first patterned groove and/or the second patterned groove, the copper trace layer including an exposed trace portion exposed outside the plastic substrate and an embedded trace portion embedded in the plastic substrate, where a height of the exposed trace portion is no more than 45 μm, a height of the embedded trace portion is the depth of the first patterned groove or the depth of the second patterned groove, a width of the exposed trace portion is greater than or equal to a width of the first patterned groove or a width of the second patterned groove, and a height/width ratio of the copper trace layer ranges from 1.5 to 3.75.

In the high-aspect-ratio flexible circuit board as mentioned above, the plastic substrate is a polyimide film, and a thickness of the polyimide film is 12 μm to 150 μm.

In the high-aspect-ratio flexible circuit board as mentioned above, the first patterned groove and/or the second patterned groove are formed on the plastic substrate by way of laser irradiation.

In the high-aspect-ratio flexible circuit board as mentioned above, a composition of the metal seed layer is selected from the group consisting of nickel, copper, chromium, and titanium.

In the high-aspect-ratio flexible circuit board as mentioned above, the flexible circuit board has a via hole, and a hole diameter of the via hole is 20 μm to 50 μm.

In the high-aspect-ratio flexible circuit board as mentioned above, the flexible circuit board is a single-sided board, a double-sided board, or a multi-layer board.

In the high-aspect-ratio flexible circuit board as mentioned above, a bottom width of the first patterned groove and/or a bottom width of the second patterned groove are each less than a top width, and a bottom width/top width ratio of the first patterned groove and/or a bottom width/top width ratio of the second patterned groove are each between 0.05 and 0.8.

For the above and other purposes, the present disclosure provides a manufacturing method for a high-aspect-ratio flexible circuit board, including the following steps: providing a plastic substrate, having a first surface and a second surface opposite to each other; forming a first patterned groove in the first surface of the plastic substrate and/or forming a second patterned groove in the second surface of the plastic substrate by way of laser, where an upper limit of a sum value of a total depth of the first patterned groove and a total depth of the second patterned groove equals a thickness of the plastic substrate minus 5 μm; forming a metal seed layer on the first surface and/or the second surface by way of electroless plating or sputtering; forming a thin copper layer on the metal seed layer on the first surface and/or the second surface by way of plating; and forming a copper trace layer on the thin copper layer on the first surface and/or the second surface by way of semi-additive process, the copper trace layer being partially embedded in the plastic substrate, and including an exposed trace portion exposed outside the plastic substrate and an embedded trace portion embedded in the plastic substrate, where a height of the exposed trace portion is not more than 45 μm, and a width of the exposed trace portion is greater than or equal to a width of the first patterned groove or a width of the second patterned groove; and a height/width ratio of the copper trace layer is ranges from 1.5 to 3.75.

In the manufacturing method for a high-aspect-ratio flexible circuit board as mentioned above, the plastic substrate is a polyimide film, and a thickness of the polyimide film is 12 μm to 150 μm.

In the manufacturing method for a high-aspect-ratio flexible circuit board as mentioned above, a wavelength of the laser is 150 nm to 1100 nm.

In the manufacturing method for a high-aspect-ratio flexible circuit board as mentioned above, while or after forming a first patterned groove in the first surface of the plastic substrate and/or forming a second patterned groove in the second surface of the plastic substrate, the method further includes: drilling a via hole in the plastic substrate by way of laser, where a hole diameter of the via hole is 20 μm to 50 μm.

In the manufacturing method for a high-aspect-ratio flexible circuit board as mentioned above, a composition of the metal seed layer is selected from the group consisting of nickel, copper, chromium, and titanium.

In the manufacturing method for a high-aspect-ratio flexible circuit board as mentioned above, a thickness of the thin copper layer is 0.2 μm to 3 μm.

In the manufacturing method for a high-aspect-ratio flexible circuit board as mentioned above, a bottom width of the first patterned groove and/or a bottom width of the second patterned groove are each less than a top width, and a bottom width/top width ratio of the first patterned groove and/or a bottom width/top width ratio of the second patterned groove are each between 0.05 and 0.8.

The high-aspect-ratio flexible circuit board as mentioned above can avoid the problem that the dry-film photoresist on the high-aspect-ratio flexible circuit board peels off due to the limited standing area.

### BRIEF DESCRIPTION OF THE DRAWINGS

FIG. 1 is a schematic cross-sectional view of a high-aspect-ratio flexible circuit board of Embodiment 1.

FIG. 2 is a flow chart illustrating a manufacturing of a high-aspect-ratio flexible circuit board of Embodiment 1.

FIG. 3 is a three-dimensional schematic diagram illustrating a processing of a high-aspect-ratio flexible circuit board of Embodiment 1.

FIG. 4 is a schematic cross-sectional view of a high-aspect-ratio flexible circuit board of Embodiment 2.

FIG. 5 is a structural schematic diagram of each Experimental Example in a resistance quality test for a high-aspect-ratio flexible circuit board.

FIG. 6 is a cross-sectional photo of processed patterned grooves of Experimental Example 19 in a laser processing mode comparative test for a high-aspect-ratio flexible circuit board.

FIG. 7 is a cross-sectional photo of processed patterned grooves of Experimental Example 20 in a laser processing mode comparative test for a high-aspect-ratio flexible circuit board.

FIG. 8 is a cross-sectional photo of processed patterned grooves of Experimental Example 21 in a laser processing mode comparative test for a high-aspect-ratio flexible circuit board.

FIG. 9 is a cross-sectional photo of processed patterned grooves of Experimental Example 22 in a laser processing mode comparative test for a high-aspect-ratio flexible circuit board.

### DETAILED DESCRIPTION OF THE INVENTION

The following describes the implementation of the present disclosure through specific embodiments, and those skilled in the art can understand other advantages and effects of the present disclosure from the content disclosed in this description. The present disclosure can also be implemented or applied through other different specific embodiments, and various details in this description can be modified and changed based on different viewpoints and applications without departing from the spirit of the present disclosure.

Unless otherwise stated herein, the term “A to B” used in this description and the appended claims includes the meaning of “A or above and B or less”. For example, the term “10 wt % to 40 wt %” includes the meaning of “10 wt % or above and 40 wt % or less”.

### High-Aspect-Ratio Flexible Circuit Board of Embodiment 1

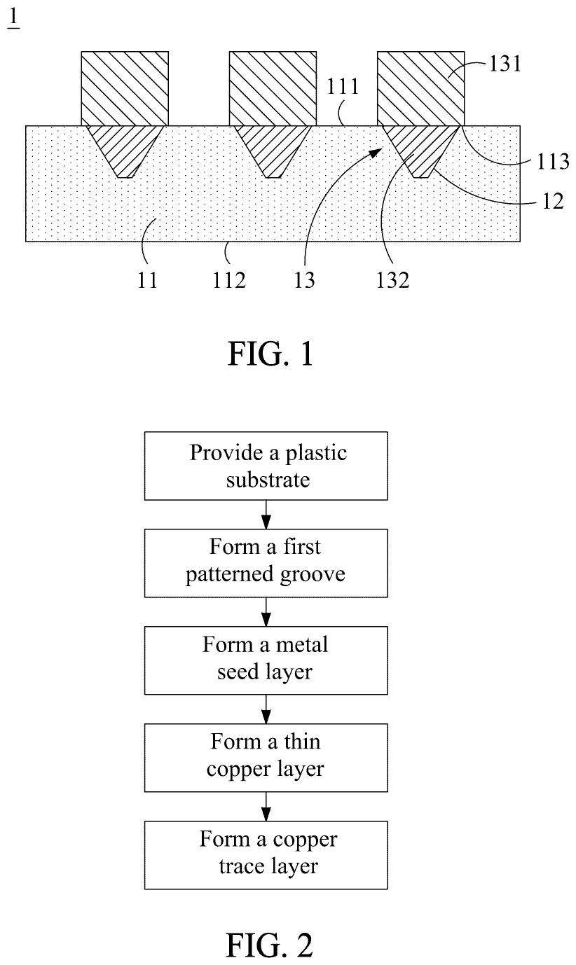

The high-aspect-ratio flexible circuit board 1 of Embodiment 1 is as shown in FIG. 1. The high-aspect-ratio flexible circuit board 1 includes a plastic substrate 11, a metal seed layer 12, and a copper trace layer 13. The plastic substrate 11 includes a first surface 111 and a second surface 112 opposite to each other, where a first patterned groove 113 is formed in the first surface 111, and an upper limit of a total depth of the first patterned groove 113 equals a thickness of the plastic substrate 11 minus 5 μm. The metal seed layer 12 is formed on the first surface 111. The copper trace layer 13 is formed on the metal seed layer 12 corresponding to the first patterned groove 113 and the copper trace layer 13 includes an exposed trace portion 131 exposed outside the plastic substrate 11 and an embedded trace portion 132 embedded in the plastic substrate 11. A height of the exposed trace portion 131 is no more than 45 μm, a height of the embedded trace portion 132 is the depth of the first patterned groove 113, a width of the exposed trace portion 131 is greater than or equal to a width of the first patterned groove 113, and a height/width ratio of the copper trace layer 13 ranges from 1.5 to 3.75.

### Plastic Substrate 11

The plastic substrate 11 of Embodiment 1 is a polyimide film, and a thickness of the polyimide film ranges from 12 μm to 150 μm, e.g., 12 μm, 20 μm, 30 μm, 40 μm, 50 μm, 60 μm, 70 μm, 80 μm, 90 μm, 100 μm, 110 μm, 120 μm, 130 μm, 140 μm, or 150 μm. Additionally, a polyimide substrate can also be made of transparent polyimide, e.g., polyimide with light transmittance greater than 87%. In addition, the polyimide substrate may be a commercially available product, e.g., a polyimide film manufactured by Taimide Tech. Inc., with a model number TX6 series. In other embodiments, the plastic substrate 11 can use other existing materials that can be used as the plastic substrate of the flexible circuit board as required, and is not limited to Embodiment 1. Additionally, the flexible circuit board is a single-sided board, a double-sided board, or a multi-layer board.

### Metal Seed Layer 12

A composition of the metal seed layer 12 can be selected from at least one of nickel, copper, chromium, and titanium, and may include other materials that can be formed on the metal seed layer 12 of the plastic substrate 11.

Manufacturing Method for High-Aspect-Ratio Flexible Circuit Board of

### Embodiment 1

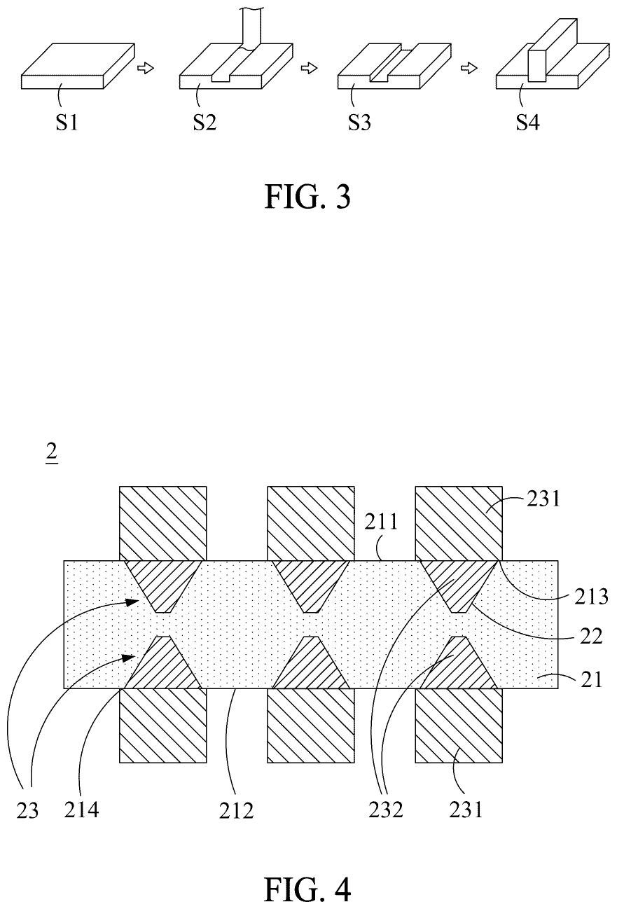

Firstly, referring to FIG. 2 and FIG. 3, FIG. 2 is a flow chart illustrating a manufacturing of a high-aspect-ratio flexible circuit board of Embodiment 1. FIG. 3 is a three-dimensional schematic diagram illustrating a processing of a high-aspect-ratio flexible circuit board of Embodiment 1. A manufacturing flow for the high-aspect-ratio flexible circuit board of Embodiment 1 at least includes the following steps: providing a plastic substrate (which may correspond to S1 in FIG. 3), having a first surface and a second surface opposite to each other; forming a first patterned groove in the first surface of the plastic substrate by way of laser (which may correspond to S2 in FIG. 3), where an upper limit of a total depth of the first patterned groove equals a thickness of the plastic substrate minus 5 μm; forming a metal seed layer on the first surface by way of electroless plating or sputtering; forming a thin copper layer (generally between 0.2 μm and 3 μm in thickness) on the metal seed layer on the first surface by way of plating (which may correspond to S3 in FIG. 3); and forming a copper trace layer on the thin copper layer on the first surface by way of semi-additive process (which may correspond to S4 in FIG. 3), where the copper trace layer is partially embedded in the plastic substrate, and the copper trace layer includes an exposed trace portion exposed outside the plastic substrate and an embedded trace portion embedded in the plastic substrate, a height of the exposed trace portion is not more than 45 μm, and a width of the exposed trace portion is greater than or equal to a width of the first patterned groove; and a height/width ratio of the copper trace layer is ranges from 1.5 to 3.75.

The manufacturing flow for the high-aspect-ratio flexible circuit board of Embodiment 1 will be specifically described below.

Firstly, a roll of polyimide film was taken as the plastic substrate 11. The polyimide film was purchased from Taimid Tech. Inc., with the model number TX6-025.

Then, continuous processing was performed on the plastic substrate 11 by way of UV laser to manufacture a first patterned groove 113 (In other embodiments, via holes with a hole diameter of 20 μm to 50 μm can be drilled simultaneously or successively). The wavelength of the aforementioned laser was 355 nm (which may be selected within the range of 150 nm to 1100 nm, and applicable laser wavelength values were adjusted in increments of 100 nm). The energy and the number of processing cycles were adjusted according to the pattern depth. For the drilling operation, the energy was fixed at 1 W, and the number of processing cycles was 3. A UV laser processing machine used in Embodiment 1 was purchased from MKS Instruments, Inc., with the model number ESI/5335.

After the aforementioned processing, substrate cleaning was carried out, that is, a surface of the plastic substrate 11 and the via hole were cleaned with plasma, so as to remove splash and pollutants caused by laser processing. The energy of the plasma was 8 W to 10 W, and a treatment speed was 3 m/min. In Embodiment 1, the aforementioned plasma treatment was carried out using a roll-to-roll plasma treatment machine (purchased from CREATING NANO TECHNOLOGIES INC.).

After the cleaning of the plastic substrate 11, the aforementioned plastic substrate 11 processed by way of laser was electrolessly nickel-plated (sputtering can also be used), and both the surface of the plastic substrate 11 and an interior of the via hole were plated simultaneously to form the metal seed layer 12. The treatment speed of electroless nickel plating was 1.2 m/min, the nickel bath temperature was 34° C., and finally, the metal seed layer 12 was obtained, with a thickness of about 70 μm to 100 μm. The aforementioned electroless nickel plating was carried out using roll-to-roll nickel copper-plated wire (purchased from FUJICHEM PRECISION MACHINERIES, INC.) and SLP-series electroless nickel plating reagents (purchased from OKUNO Chemical Industries Co., Ltd., Japan).

After the metal seed layer 12 was formed on the plastic substrate 11, plating was carried out on the metal seed layer 12 using a copper sulfate plating solution to form a base copper layer. The treatment speed of base copper plating is 0.9 m/min, the current density of each plating bath was controlled to be 0.6 ASD to 1.2 ASD, and finally, the base copper layer with a thickness of 1 μm was obtained. The aforementioned base copper plating was carried out using a roll-to-roll copper-plated wire (purchased from JX Nippon Mining & Metals Corporation), a formula a plating additive (containing a copper sulfate plating solution, sulfuric acid, copper oxide powder) (purchased from All-In-Line Chemicals Enterprise Co., Ltd.) and a formula b plating additive (containing a gloss agent and a leveling agent) (purchased from JCU TAIWAN Corporation).

After the plastic substrate 11 was plated with the base copper layer, the surface roughening treatment was further carried out, that is, the surface of the aforementioned base copper layer was roughened with a hydrochloric acid series micro-etching solution to increase the adhesion of a photoresist dry film. The copper etching amount of the aforementioned surface roughening treatment was 0.2 μm to 1.0 μm, and the surface roughening treatment was carried out using a horizontal roughening line (purchased from FUJICHEM PRECISION MACHINERIES, INC.) and a roughening process solution (purchased from MEC TAIWAN COMPANY LTD, with the model number UT-4100).

After the aforementioned surface roughening treatment, film lamination treatment was carried out, that is, a negative dry-film photoresist was attached to the surface of the aforementioned base copper layer by way of hot pressing, and the thickness of the negative dry-film photoresist was determined from the trace height and trace width and spacing. The lamination operation temperature in film lamination treatment was 90° C. to 110° C. and the pressure was 1 Kgf/cm² to 3 Kgf/cm². The aforementioned film lamination treatment was carried out using a roll-to-roll laminator (purchased from C SUN MFG. LTD., with the model number RTR-500PH), and the negative dry-film photoresist used was an exposure and development dry film (purchased from Thirty Power Technology Corporation, with the model number RESONAC/RD-1260).

After film laminator treatment, exposure treatment was then carried out, that is, a trace pattern was exposed on the aforementioned negative dry-film photoresist by using a laser direct imager (LDI) (purchased from HuaZhan Optoelectronic Co., Ltd., with the model number ORC/RDI-10Duo). The exposure energy was controlled to be 15 stops to 19 stops (41-stop sensitivity guide film).

After the exposure treatment, development treatment was then carried out, and an unpolymerized dry film is washed off with a sodium bicarbonate developing solution to expose the aforementioned bottom base copper layer, where the aforementioned base copper layer was used as a base for subsequent copper plating. The aforementioned exposure treatment was carried out using sodium bicarbonate with a concentration of about 1% (purchased from All-In-Line Chemicals Enterprise Co., Ltd.), and the development time was 40 seconds to 120 seconds. The aforementioned exposure treatment was carried out using a horizontal developing line (purchased from FUJICHEM PRECISION MACHINERIES, INC.).

After development treatment, copper plating was then carried out to form a preliminary copper trace layer, that is, the aforementioned exposed base copper layer was copper-plated using a copper sulfate plating solution to form a trace, and voids of the aforementioned via holes are also copper-plated. The acid:copper weight ratio of the copper sulfate plating solution was about 2:1, and the copper plating current density was 0.8 ASD to 1.5 ASD. The aforementioned copper plating treatment was carried out using a vertical copper-plated wire (purchased from Commend Machinery Co., Ltd.), a formula a plating additive (copper sulfate plating solution, sulfuric acid, copper oxide powder) (purchased from All-In-Line Chemicals Enterprise Co., Ltd.) and a formula b plating additive (containing a gloss agent and a leveling agent) (purchased from JCU TAIWAN Corporation).

After the formation of the preliminary copper trace layer, film stripping was further carried out, and the remaining negative dry-film photoresist was stripped off using an organic film stripping solution to expose the bottom base copper layer below. At this time, base copper was present both beneath the aforementioned preliminary copper trace layer and at the side pitch of the aforementioned preliminary copper trace layer. The operating temperature of the film stripping treatment was 55° C., the concentration of the organic film stripping solution was 10% to 20%, and the treatment speed was 1 m/min to 2 m/min. The aforementioned film stripping treatment was carried out using a horizontal film stripping line (purchased from FUJICHEM PRECISION MACHINERIES, INC.) and a dry-film photoresist remover (purchased from Chemflux Co., Ltd., with the model number CXW-PS312).

After the film stripping treatment, rapid etching treatment was finally carried out. In the aforementioned rapid etching treatment, the aforementioned exposed base copper layer and the metal seed layer were removed using a sulfuric acid-hydrogen peroxide solution, allowing the aforementioned preliminary copper trace layer to be formed into a copper trace layer 13 with independent trace patterns. Thus, the high-aspect-ratio flexible circuit board 1 of Embodiment 1 can be manufactured. The copper trace layer was formed by way of semi-additive processing. The operating temperature of the aforementioned rapid etching treatment was 30° C., and the treatment speed was 0.5 m/min to 1.5 m/min. The aforementioned rapid etching treatment was carried out using a horizontal rapid etching line (purchased from FUJICHEM PRECISION MACHINERIES, INC.) and a sulfuric acid-hydrogen peroxide series micro-etching solution (purchased from JCU TAIWAN Corporation, with the model number SAC2).

### High-Aspect-Ratio Flexible Circuit Board 2 of Embodiment 2

The high-aspect-ratio flexible circuit board 2 of Embodiment 2 is as shown in FIG. 4, and its structure is roughly similar to that of the high-aspect-ratio flexible circuit board 1 of Embodiment 1. The main difference is that both the first surface and the second surface of the high-aspect-ratio flexible circuit board 2 are formed with copper traces. The high-aspect-ratio flexible circuit board 2 includes a plastic substrate 21, two metal seed layers 22, and two copper trace layers 23. The plastic substrate 21 includes a first surface 211 and a second surface 212 opposite to each other, where a first patterned groove 213 is formed in the first surface 211, a second patterned groove 214 is formed in the second surface 212, and the upper limit of the sum value of the total depth of the first patterned groove 213 and the total depth of the second patterned groove 214 equals the thickness of the plastic substrate 21 minus 5 μm. The two metal seed layers 22 are formed on the first surface 211 and on the second surface 212, respectively. The two copper trace layers 23 are respectively formed on the metal seed layers 22 corresponding to the first patterned groove 213 and the second patterned groove 214 and each of the copper trace layers 23 includes an exposed trace portion 231 exposed outside the plastic substrate 21 and an embedded trace portion 232 embedded in the plastic substrate 21. The height of the exposed trace portion 231 is no more than 45 μm, the height of the embedded trace portion 232 is the depth of the first patterned groove 213 or the depth of the second patterned groove 214, the width of the exposed trace portion 231 is greater than or equal to the width of the first patterned groove 213 or the width of the second patterned groove 214, and the height/width ratio of the copper trace layer 23 ranges from 1.5 to 3.75.

The manufacturing process of the high-aspect-ratio flexible circuit board 2 is substantially the same as that of Embodiment 1. The only difference is that in Embodiment 2, continuous processing is performed on the plastic substrate 21 by way of UV laser to manufacture the first patterned groove 213 and the second patterned groove 214, which will not be repeated here.

### Resistance Quality Test for High-Aspect-Ratio Flexible Circuit Board

In the following tests, the single-sided high-aspect-ratio flexible circuit boards and the double-sided high-aspect-ratio flexible circuit boards in Tables 1 and 2 will be manufactured according to the manufacturing method for a high-aspect-ratio flexible circuit board in the aforementioned Embodiments 1 and 2, and the resistance quality of different high-aspect-ratio flexible circuit boards will be tested. The methods and instruments used for structural measurement and resistance quality test for different high-aspect-ratio flexible circuit boards are as follows.

The coating thickness was measured using an X-ray Fluorescence Spectrometer (XRF) which was purchased from TechMax Technical Group. The model is Olympus/Vanta C series. A specific measurement method for the coating thickness is to place a 510 cm*5 cm of test sample at an X-ray emission place of the X-ray Fluorescence Spectrometer, close the outer cover of the X-ray Fluorescence Spectrometer, click the Coating mode on operating software and select conditions and parameters, and press the start key to measure the coating thickness.

The thickness of electroplated copper was measured using a Copper Thickness Meter which was purchased from Shin Shen Instruments Co., Ltd. with the model number Oxford Instruments/CMI760. A specific measurement method for the thickness of the electroplated copper is to place a sample on a measuring bench, and contact a four-point probe uniformly with the copper surface of a flexible copper clad laminate (FCCL) plated with a thin copper layer at a measurement point to measure the thickness of the copper layer.

The trace height was measured using a laser confocal and white light interference microscope which was purchased from Keyence Taiwan Co., Ltd., with the model number VK-X3050. A specific measurement method for the trace height is to place the high-aspect-ratio flexible circuit board on the observation stage of a microscope, select an appropriate magnification lens, start a white light measurement mode, and press Start to obtain the trace height.

The trace width was measured using a Metallographic Microscope, which was purchased from Lin Trading Co., Ltd. with the model number Nikon/LV100ND. A specific measurement method for the trace width is to place the high-aspect-ratio flexible circuit board on the observation stage of a Metallographic Microscope, examine the trace with a 20× objective lens, and measure the trace width with measurement software.

The trace resistance was measured using a LCR Meter, which was purchased from Chawei Co., Ltd. with the model number LCR700. A specific measurement method for the trace resistance is to reset the LCR Meter to zero, and then press a probe on a test point at a measurement point to obtain the resistance value of a trace.

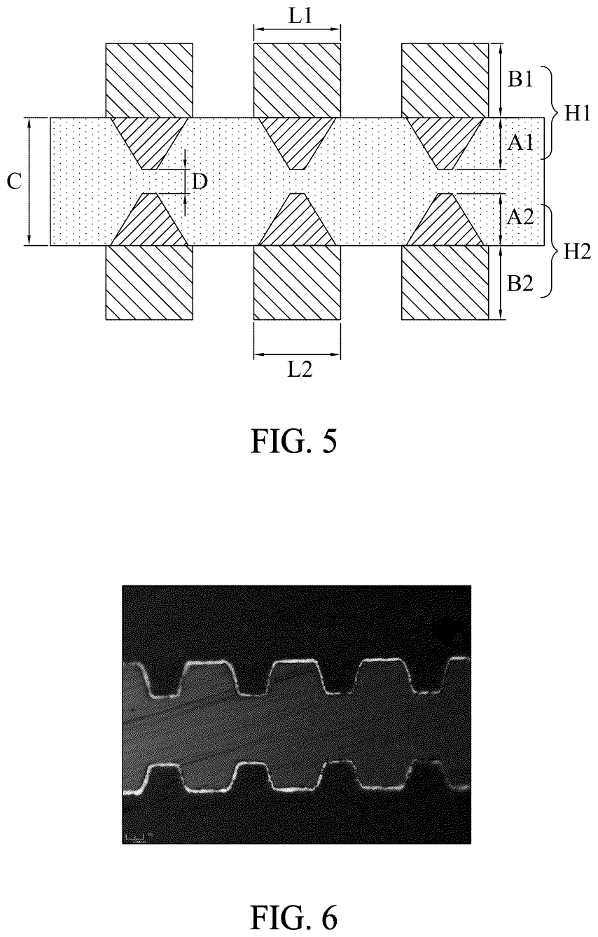

The structural measurement and overall quality table of the aforementioned high-aspect-ratio flexible circuit board are as shown in tables 1-1 to 1-3 below, and also, references are made to the structural schematic diagram of the Experimental Example in FIG. 5.

Table 1-1 to Table 1-2. Circuit Board Structures for Experimental Examples 1-18

TABLE 1-1

| | | | | | | | First | Second | First |
|---|---|---|---|---|---|---|---|---|---|
| | | | First | Second | First | Second | surface | surface | surface |
| | | Plastic | surface | surface | surface | surface | exposed | exposed | overall |
| | | substrate | trace | trace | grooving | grooving | trace | trace | trace |
| Experimental | Product | thickness | width | width | depth | depth | height | height | height |
| Examples | type | C | L1 | L2 | A1 | A2 | B1 | B2 | H1 |
| 1 | Single- | 25 | 30 | 0 | 0 | 0 | 40 | 0 | 40 |
| | sided | | | | | | | | |
| | board | | | | | | | | |
| 2 | Single- | 25 | 29.7 | 0 | 6 | 0 | 37.5 | 0 | 43.5 |
| | sided | | | | | | | | |
| | board | | | | | | | | |
| 3 | Single- | 25 | 30.2 | 0 | 10 | 0 | 35 | 0 | 45 |
| | sided | | | | | | | | |
| | board | | | | | | | | |
| 4 | Single- | 25 | 30.5 | 0 | 14 | 0 | 32 | 0 | 46 |
| | sided | | | | | | | | |
| | board | | | | | | | | |
| 5 | Single- | 25 | 29.6 | 0 | 20 | 0 | 30 | 0 | 50 |
| | sided | | | | | | | | |
| | board | | | | | | | | |
| 6 | Single- | 25 | 30.1 | 0 | 22 | 0 | 28.5 | 0 | 50.5 |
| | sided | | | | | | | | |
| | board | | | | | | | | |
| 7 | Single- | 25 | 30 | 0 | 0 | 0 | 40 | 0 | 40 |
| | sided | | | | | | | | |
| | board | | | | | | | | |
| 8 | Single- | 25 | 29.7 | 0 | 5 | 0 | 39 | 0 | 44 |
| | sided | | | | | | | | |
| | board | | | | | | | | |
| 9 | Single- | 25 | 29.6 | 0 | 9 | 0 | 38.5 | 0 | 47.5 |
| | sided | | | | | | | | |
| | board | | | | | | | | |
| 10 | Single- | 25 | 30.1 | 0 | 16 | 0 | 40 | 0 | 56 |
| | sided | | | | | | | | |
| | board | | | | | | | | |
| 11 | Single- | 25 | 30.3 | 0 | 20 | 0 | 41 | 0 | 61 |
| | sided | | | | | | | | |
| | board | | | | | | | | |
| 12 | Single- | 25 | 30.3 | 0 | 22 | 0 | 41 | 0 | 63 |
| | sided | | | | | | | | |
| | board | | | | | | | | |
| 13 | Double- | 50 | 30 | 30 | 0 | 0 | 40 | 40 | 40 |
| | sided | | | | | | | | |
| | board | | | | | | | | |
| 14 | Double- | 50 | 30 | 29.8 | 19 | 19 | 39 | 38 | 58 |
| | sided | | | | | | | | |
| | board | | | | | | | | |
| 15 | Double- | 50 | 24.8 | 25 | 0 | 0 | 40 | 39 | 40 |
| | sided | | | | | | | | |
| | board | | | | | | | | |
| 16 | Double- | 50 | 25.2 | 25.3 | 18 | 19 | 41 | 42 | 59 |
| | sided | | | | | | | | |
| | board | | | | | | | | |
| 17 | Double- | 50 | 21.2 | 22.5 | 0 | 0 | 43 | 41 | 43 |
| | sided | | | | | | | | |
| | board | | | | | | | | |
| 18 | Double- | 50 | 21.5 | 22 | 23 | 22 | 44 | 43 | 67 |
| | sided | | | | | | | | |
| | board | | | | | | | | |
| 19 | Double- | 25 | 30 | 30 | 0 | 0 | 50 | 50 | 50 |
| | sided | | | | | | | | |
| | board | | | | | | | | |
| 20 | Double- | 75 | 20 | 20 | 35 | 35 | 45 | 45 | 80 |
| | sided | | | | | | | | |
| | board | | | | | | | | |

TABLE 1-2

| | | Second surface | Insulation | Aspect ratio | Aspect ratio |
|---|---|---|---|---|---|
| | | overall trace | layer | of traces on | of traces on |
| Experimental | Product | height | thickness | first | second |
| Examples | type | H2 | D | surface | surface |
| 1 | Single- | 0 | 25 | 1.33 | N/A |
| | sided board | | | | |
| 2 | Single- | 0 | 19 | 1.46 | N/A |
| | sided board | | | | |
| 3 | Single- | 0 | 15 | 1.49 | N/A |
| | sided board | | | | |
| 4 | Single- | 0 | 11 | 1.51 | N/A |
| | sided board | | | | |
| 5 | Single- | 0 | 5 | 1.69 | N/A |
| | sided board | | | | |
| 6 | Single- | 0 | 3 | 1.68 | N/A |
| | sided board | | | | |
| 7 | Single- | 0 | 25 | 1.33 | N/A |
| | sided board | | | | |
| 8 | Single- | 0 | 20 | 1.48 | N/A |
| | sided board | | | | |
| 9 | Single- | 0 | 16 | 1.60 | N/A |
| | sided board | | | | |
| 10 | Single- | 0 | 9 | 1.86 | N/A |
| | sided board | | | | |
| 11 | Single- | 0 | 5 | 2.01 | N/A |
| | sided board | | | | |
| 12 | Single- | 0 | 3 | 2.08 | N/A |
| | sided board | | | | |
| 13 | Double- | 40 | 50 | 1.33 | 1.33 |
| | sided board | | | | |
| 14 | Double- | 57 | 12 | 1.93 | 1.91 |
| | sided board | | | | |
| 15 | Double- | 39 | 50 | 1.61 | 1.56 |
| | sided board | | | | |
| 16 | Double- | 61 | 13 | 2.34 | 2.41 |
| | sided board | | | | |
| 17 | Double- | 41 | 50 | 2.03 | 1.82 |
| | sided board | | | | |
| 18 | Double- | 65 | 5 | 3.12 | 2.95 |
| | sided board | | | | |
| 19 | Double- | 50 | 25 | 1.67 | 1.67 |
| | sided board | | | | |
| 20 | Double- | 80 | 5 | 4.00 | 4.00 |
| | sided board | | | | |

TABLE 1-3
Overall Quality Table of Experimental Examples 1-18

| | | First | Second | | | | |
|---|---|---|---|---|---|---|---|
| | | surface | surface | | | | |
| Experimental | Product | trace | trace | Production | Electrical | Manufacturing | Overall |
| Examples | type | resistance | resistance | yield | performance | costs | evaluation |
| 1 | Single- | 2.02 | N/A | Average | Average | N/A | Δ |
| | sided | | | | | | |
| | board | | | | | | |
| 2 | Single- | 2.00 | N/A | Slightly | Average | Slightly | ◯ |
| | sided | | | higher | | down | |
| | board | | | | | | |
| 3 | Single- | 1.99 | N/A | Slightly | Average | Decline | ⊚ |
| | sided | | | higher | | | |
| | board | | | | | | |
| 4 | Single- | 2.01 | N/A | High | Average | Decline | ⊚ |
| | sided | | | | | | |
| | board | | | | | | |
| 5 | Single- | 2.01 | N/A | High | Average | Decline | ⊚ |
| | sided | | | | | | |
| | board | | | | | | |
| 6 | Single- | 1.99 | N/A | High | Slightly | N/A | X |
| | sided | | | defect | lower | | |
| | board | | | rate of | | | |
| | | | | exposed | | | |
| | | | | trace | | | |
| 7 | Single- | 2.02 | N/A | Average | Average | N/A | Δ |
| | sided | | | | | | |
| | board | | | | | | |
| 8 | Single- | 1.96 | N/A | Average | Slightly | Slightly up | ◯ |
| | sided | | | | lower | | |
| | board | | | | | | |
| 9 | Single- | 1.89 | N/A | Average | Slightly | Slightly up | ◯ |
| | sided | | | | lower | | |
| | board | | | | | | |
| 10 | Single- | 1.66 | N/A | Average | Decline | Slightly up | ⊚ |
| | sided | | | | | | |
| | board | | | | | | |
| 11 | Single- | 1.54 | N/A | Average | Decline | Slightly up | ⊚ |
| | sided | | | | | | |
| | board | | | | | | |
| 12 | Single- | 1.51 | N/A | High | Decline | N/A | X |
| | sided | | | defect | | | |
| | board | | | rate of | | | |
| | | | | exposed | | | |
| | | | | trace | | | |
| 13 | Double- | 2.2 | 2.2 | Average | Average | N/A | Δ |
| | sided | | | | | | |
| | board | | | | | | |
| 14 | Double- | 1.8 | 1.8 | Average | Decline | Slightly up | ⊚ |
| | sided | | | | | | |
| | board | | | | | | |
| 15 | Double- | 2.7 | 2.7 | Average | Elevated | N/A | X |
| | sided | | | | | | |
| | board | | | | | | |
| 16 | Double- | 2.1 | 2.0 | Average | Slightly | Slightly up | ⊚ |
| | sided | | | | lower | | |
| | board | | | | | | |
| 17 | Double- | 2.9 | 2.9 | Slightly | Elevated | N/A | X |
| | sided | | | lower | | | |
| | board | | | | | | |
| 18 | Double- | 2.2 | 2.2 | Slightly | Average | Slightly up | ⊚ |
| | sided | | | lower | | | |
| | board | | | | | | |
| 19 | Double- | 12 | 12 | Trace | N/A | N/A | X |
| | sided | | | short | | | |
| | board | | | problem | | | |
| | | | | in trace | | | |
| 20 | Double- | 11 | 11 | Increased | N/A | N/A | X |
| | sided | | | resistance | | | |
| | board | | | due to | | | |
| | | | | dents in | | | |
| | | | | trace | | | |

Overall evaluation symbols: X (Poor); Δ (Acceptable); ◯ (Good); ⊚ (Excellent)

According to the test results of the above Experimental Examples 1 to 6, it can be seen that under the conditions of the same plastic substrate thickness (C), the same first surface trace width (L1) and the same trace cross-sectional area, when the first surface grooving depth (A1) increases, the first surface exposed trace height (B1) will decrease, which will directly affect the thickness of a solder mask. Since the thickness of the solder mask decreases, its price will also decrease. Therefore, the material costs can be effectively reduced.

According to the test results of the above Experimental Examples 7 to 12, it can be seen that under the same plastic substrate thickness (C), the same first surface trace width (L1) and the same first surface exposed trace height (B1), when the first surface grooving depth (A1) increases, the first surface overall trace height (H1) will decrease, thereby directly reducing the first surface trace resistance (R1).

Without changing the coil density of the flexible board, the product can bear heavier current, allowing the actuation benefit of a coil product is higher.

According to the test results of the above Experimental Examples 13 to 18, it can be seen that under the same plastic substrate thickness (C), the same first surface exposed trace height (B1) and the same second surface exposed trace height (B2), when the first surface grooving depth (A1) and the second surface grooving depth (A2) increase, the first surface trace width (L1) and the second surface trace width (L2) may decrease, thereby directly affecting the density of traces and achieving the effect of reducing the product size, and thus improving the board space utilization and reducing the costs accordingly.

According to the overall quality table of the aforementioned Experimental Examples 1 to 18, it can be seen that the thickness (D) of an insulation plastic substrate (that is, the insulation layer thickness D) at the bottom of the groove of the above-mentioned high-aspect-ratio flexible circuit board must be greater than or equal to 5 μm. If the thickness of the double-sided board is less than this numerical value, there will be a problem of trace short failure between upper and lower layer traces (referring to Experimental Example 12), and if the thickness of the single-sided board is less than this numerical value, there will be a problem of current leakage failure caused by exposed traces (referring to Experimental Example 6). The overall evaluation in Table 1-3 above is based on the overall evaluation of three indicators: production yield, electrical performance and manufacturing cost. It can also be seen from the overall evaluation that the overall evaluation of Experimental Examples 6 and 12 is poor.

The trace height of the exposed trace portion of the copper trace layer should be equal to or less than 45 μm. If the height is higher than this numerical value, the dry film will be difficult to strip off, resulting in film residue defects, thereby leading to trace short failure (referring Experimental Example 19). From the overall evaluation, it can also be seen that the overall evaluation of Experimental Example 19 is poor.

The ratio of the overall trace height/trace width of the copper trace layer should be less than 3.75. If the ratio exceeds this range, bubbles will be produced on the traces due to poor circulation, forming voids or dimples, thereby leading to an increase in trace resistance (referring Experimental Example 20). From the overall evaluation, it can also be seen that the overall evaluation of Experimental Example 20 is poor. The ratio of the overall trace height/trace width of the copper trace layer has to be greater than 1.5. If the ratio is less than this range, refer to the results of Experimental Example 13, the resistance and yield of the circuit board are relatively average, and the overall evaluation is poor. Therefore, the circuit board is not suitable for voice coil motors.

Laser Processing Mode Comparative Test for High-Aspect-Ratio Flexible Circuit Board

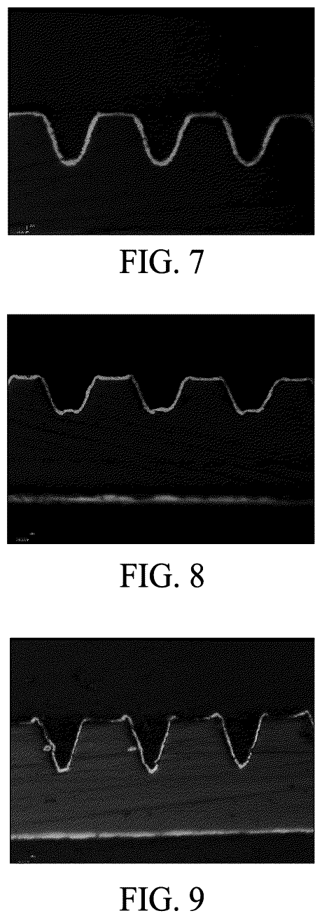

The following test is to test changes in bottom widths and top widths of processed patterned grooves with different processing methods and different laser wavelengths. The parameters for different processing methods and bottom widths and top widths of correspondingly formed patterned groove are as shown in Table 3 below, while FIG. 6 to FIG. 9 further show the cross-sectional photos of the processed patterned grooves.

Table 2. Bottom Width and Top Width of Patterned Grooves for Experimental Examples 21-24

TABLE 2

| | Experimental Examples | | | |
|---|---|---|---|---|
| | 21 | 22 | 23 | 24 |
| | Processing mode | | | |
| | Excimer laser | | Picosecond UV | |
| | (with | Femtosecond | laser (with | Nanosecond |
| | photomask) | IR laser | photomask) | UV laser |
| Wavelength of laser | 248 | 1064 | 355 | 355 |
| (nm) | | | | |
| Groove depth (μm) | 12.7 | 22.9 | 15.3 | 22.5 |
| Groove top width | 19.2 | 25.3 | 24.6 | 19.8 |
| (μm) | | | | |
| Groove bottom | 13.4 | 10.4 | 9.1 | 1.6 |
| width (μm) | | | | |
| Bottom width/top | 0.70 | 0.41 | 0.37 | 0.08 |
| width | | | | |

According to the results in Table 3, it can be known that the bottom width of each of the above-mentioned laser processed grooves is less than the top width, and the ratio of the bottom width to the top width is between 0.05 and 0.8, and the width of the exposed trace must be greater than or equal to the top width of the patterned groove.

With the grooved design of the high-aspect-ratio flexible circuit board provided in the above-mentioned embodiment, the aspect ratio of the dry film can be effectively reduced, and the via holes can be made once at the same time. At the same time, since the inter-trace spacing depth on the top of the circuit board is shallower, the processing difficulty of the solder mask and bubbles are effectively reduced. Moreover, the processing method for a high-aspect-ratio flexible circuit board allows for a relatively thick plastic substrate to be used for processing, which can improve the workability and improve the common problems of crushing and fracturing in the production of flexible boards. When the plastic substrate is relatively thick, the material has better rigidity and high dimensional stability. That is, the design of the high-aspect-ratio flexible circuit board in the above-mentioned embodiment makes the traces partially embedded in the plastic substrate, which can solve the problem that the dry-film photoresist on the high-aspect-ratio flexible circuit board peels off due to the limited standing area. Moreover, the above-mentioned semi-embedded design can not only effectively reduce the aspect ratio of dry film development, improve the problem of poor copper plating yield, but also strengthen the joint between the trace and the plastic substrate, thereby obtaining a high-aspect-ratio flexible circuit board with high reliability.

The high-aspect-ratio flexible circuit board provided in the above-mentioned embodiment also has the following advantages. 1. The dimensional stability is good. 2. The operability is good: The material has sufficient stiffness, is relatively resistant to stretching, and is not prone to deformation and crushing and fracturing. 3. Fine trace width and high copper thickness can be formed: By semi-embedding a trace in combination with a dry film, a trace with fine trace width and high copper thickness can be obtained. 4. The demands and costs of solder mask materials are reduced: Relatively thin solder mask materials can be used, which can reduce the costs and reduce the bubbles. 5. The traces and the via holes can be made once: In combination with a metallization and modified semi-additive process (mSAP), the copper plating of the via holes and the copper plating of the traces can be completed once, without additional copper metallization on the via holes, which can effectively reduce the costs. 6. Electroless nickel immersion gold (ENIG) erosion is resisted: Since the metal seed layer is in the plastic base layer, the bottom of the trace will not be attacked by a solution for replacing gold, preventing erosion abnormality. 7. The high-speed circuit has good transmission performance: Since the grooves in the trace are formed by way of laser, the inner surface of the groove is smooth, and there is no roughness problem, and there will be no problem that the rough surface affects the signal transmission.

Although various embodiments have been described for illustrative purposes, it is obvious to those skilled in the art that various changes and improvements can be made without departing from the spirit and scope of the present disclosure as defined in the appended claims.

What is claimed is:

1. A high-aspect-ratio flexible circuit board, comprising:
a plastic substrate, comprising a first surface and a second surface opposite to each other, wherein a first patterned groove is formed in the first surface and/or a second patterned groove is formed in the second surface, and an upper limit of a sum value of a total depth of the first patterned groove and a total depth of the second patterned groove equals a thickness of the plastic substrate minus 5 μm;
a metal seed layer, formed on the first surface and/or the second surface; and
a copper trace layer, formed on the metal seed layer, and comprising an exposed trace portion exposed outside the plastic substrate and an embedded trace portion embedded in the plastic substrate,
wherein a height of the exposed trace portion is no more than 45 μm, a height of the embedded trace portion is the depth of the first patterned groove or the depth of the second patterned groove, a width of the exposed trace portion is greater than or equal to a width of the first patterned groove or a width of the second patterned groove, and a height/width ratio of the copper trace layer ranges from 1.5 to 3.75.

2. The high-aspect-ratio flexible circuit board according to claim 1, wherein the plastic substrate is a polyimide film, and a thickness of the polyimide film is 12 μm to 150 μm.

3. The high-aspect-ratio flexible circuit board according to claim 1, wherein the first patterned groove and/or the second patterned groove are/is formed on the plastic substrate by way of laser irradiation.

4. The high-aspect-ratio flexible circuit board according to claim 1, wherein a composition of the metal seed layer is selected from the group consisting of nickel, copper, chromium, and titanium.

5. The high-aspect-ratio flexible circuit board according to claim 1, wherein the flexible circuit board has a via hole, and a hole diameter of the via hole is 20 μm to 50 μm.

6. The high-aspect-ratio flexible circuit board according to claim 1, wherein the flexible circuit board is a single-sided board, a double-sided board, or a multi-layer board.

7. The high-aspect-ratio flexible circuit board according to claim 1, wherein a bottom width of the first patterned groove and/or a bottom width of the second patterned groove are/is each less than a top width, and a bottom width/top width ratio of the first patterned groove and/or a bottom width/top width ratio of the second patterned groove are/is each between 0.05 and 0.8.

8. A manufacturing method for a high-aspect-ratio flexible circuit board, comprising the following steps:
providing a plastic substrate, having a first surface and a second surface opposite to each other;
forming a first patterned groove in the first surface of the plastic substrate and/or forming a second patterned groove in the second surface of the plastic substrate by way of laser, wherein an upper limit of a sum value of a total depth of the first patterned groove and a total depth of the second patterned groove equals a thickness of the plastic substrate minus 5 μm;
forming a metal seed layer on the first surface and/or the second surface by way of electroless plating or sputtering;
forming a thin copper layer on the metal seed layer by way of plating; and
forming a copper trace layer on the thin copper layer on the first surface and/or the second surface by way of semi-additive process, the copper trace layer being partially embedded in the plastic substrate, wherein the copper trace layer comprises an exposed trace portion exposed outside the plastic substrate and an embedded trace portion embedded in the plastic substrate, a height of the exposed trace portion is not more than 45 μm, and a width of the exposed trace portion is greater than or equal to a width of the first patterned groove or a width of the second patterned groove; and a height/width ratio of the copper trace layer ranges from 1.5 to 3.75.

9. The manufacturing method for a high-aspect-ratio flexible circuit board according to claim 8, wherein the plastic substrate is a polyimide film, and a thickness of the polyimide film is 12 μm to 150 μm.

10. The manufacturing method for a high-aspect-ratio flexible circuit board according to claim 8, wherein a wavelength of the laser is 150 nm to 1100 nm.

11. The manufacturing method for a high-aspect-ratio flexible circuit board according to claim 8, wherein while or after forming the first patterned groove in the first surface of the plastic substrate and/or forming the second patterned groove in the second surface of the plastic substrate, the method further comprises: drilling a via hole in the plastic substrate by way of the laser, and a hole diameter of the via hole is 20 μm to 50 μm.

12. The manufacturing method for a high-aspect-ratio flexible circuit board according to claim 8, wherein a composition of the metal seed layer is selected from the group consisting of nickel, copper, chromium, and titanium.

13. The manufacturing method for a high-aspect-ratio flexible circuit board according to claim 8, wherein a thickness of the thin copper layer is 0.2 μm to 3 μm.

14. The manufacturing method for a high-aspect-ratio flexible circuit board according to claim 8, wherein a bottom width of the first patterned groove and/or a bottom width of the second patterned groove are/is each less than a top width, and a bottom width/top width ratio of the first patterned groove and/or a bottom width/top width ratio of the second patterned groove are/is each between 0.05 and 0.8.
